(19) United States
(12) Patent Application Publication
(10) Pub. No.: US 2026/0068653 A1
(43) Pub. Date: Mar. 5, 2026

(54) INTEGRATED CIRCUIT WITH METAL-INSULATOR-METAL CAPACITOR

(71) Applicant: Texas Instruments Incorporated, Dallas, TX (US)

(72) Inventor: Thomas Moutinho, Gorham, ME (US)

(21) Appl. No.: 18/822,081

(22) Filed: Aug. 30, 2024

(51) Int. Cl. H01L 23/522

(52) U.S. Cl. CPC H01L 23/5223; H10D 1/692

(57) ABSTRACT

An integrated circuit, with a semiconductor substrate having an upper surface and a capacitor. The capacitor includes a top conductive plate over the interconnect dielectric layer, a capacitor dielectric layer between the top conductive plate and the interconnect dielectric layer, and a bottom conductive plate touching the capacitor dielectric layer and located between the capacitor dielectric layer and the interconnect dielectric layer, the bottom conductive plate having grains no larger than 1.0 μm.

### CROSS-REFERENCE TO RELATED APPLICATION

Not applicable.

### BACKGROUND

Some examples described in this document relate to integrated circuits (ICs) and, more particularly to an IC with a metal-insulator-metal (MIM) capacitor.

ICs pervade all manners of electronic devices. Some IC applications include metal-insulator-metal (MIM) capacitors, such as radio frequency, analog circuitry, filters, and memories. A MIM capacitor is characterized as two metal layers separated by an insulating dielectric layer. The successful use of a MIM capacitor can improve one or more attributes, including high capacitive density, suitable breakdown voltage, low parasitics, and stability over certain ranges of temperature and voltage.

While MIM capacitors have myriad uses and applications, there may be a need to provide improved IC configurations that include MIM capacitors. This document provides examples that may improve on certain of the above concepts, as detailed below.

### SUMMARY

An integrated circuit, with a semiconductor substrate having an upper surface and a capacitor. The capacitor includes a top conductive plate over the interconnect dielectric layer, a capacitor dielectric layer between the top conductive plate and the interconnect dielectric layer, and a bottom conductive plate touching the capacitor dielectric layer and located between the capacitor dielectric layer and the interconnect dielectric layer, the bottom conductive plate having grains no larger than 1.0 μm.

Other aspects are also described and claimed.

### BRIEF DESCRIPTION OF THE DRAWINGS

FIG. 1 illustrates a cross-section of an IC, including a transistor and MIM capacitor formed in connection with an IC semiconductor substrate.

FIGS. 2 through 5 illustrate processing steps leading to the formation of the FIG. 1 IC.

FIG. 6 is a flow diagram of an example method summarizing various of the steps for manufacturing an IC with a MIM capacitor.

### DETAILED DESCRIPTION

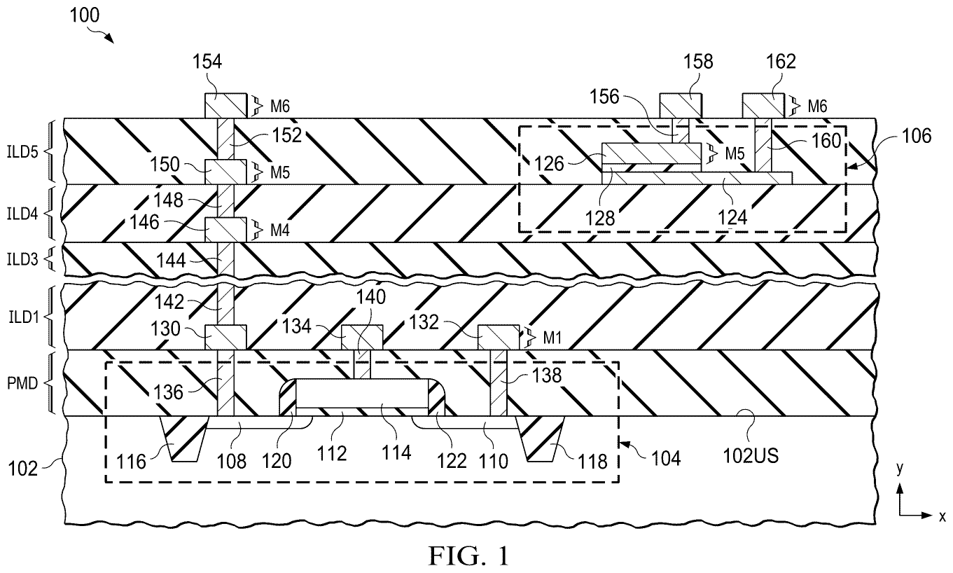

FIG. 1 illustrates a cross-section of an IC 100, sometimes referred to as a semiconductor device 100, including a semiconductor substrate 102 and formed with it a transistor 104 and a MIM capacitor 106. The substrate 102 may be a portion of a semiconductor wafer, such as a silicon wafer, of which the IC 100 is formed on one of a plurality of nominally identical die. The transistor 104 is shown as one example of a circuit device that may be formed as part of the IC 100, while other circuit devices (active or passive) may be formed either in addition to, or in lieu of, the transistor 104. Further, any such circuit device, including the transistor 104, may be electrically connected or coupled in part to either of the metal plates (or terminal elements) of the MIM capacitor 106, which are further detailed below. In FIG. 1 and various later figures, cross-sectional views are shown in an x/y (horizontal-vertical) plane but should be understood to also have features in the z-dimension, extending in a direction in and out of the illustrated x/y image plane.

The transistor 104 is, in an example, a metal-oxide-semiconductor (MOS) transistor, which generally includes a first source/drain region 108, a second source/drain region 110, a gate dielectric 112, and a gate 114. The first and second source/drain regions 108 and 110 are formed by positioning impurities in a semiconductor area, which may be within the semiconductor substrate 102, or within a doped well in the substrate 102 or a layer formed on the substrate 102. While not explicitly indicated, the first and second source/drain region 108 and 110 may include additional portions, or regions, of differing amount of impurities (e.g., laterally-diffused drain (LDD) regions). The gate dielectric 112 may be implemented by forming (e.g., growing) an oxide over an upper surface 102US of the substrate 102, which may be patterned and etched after a conductive layer, e.g. a metal or doped polysilicon layer—which will provide the gate 114—is first formed over the gate dielectric 112. The transistor 104 also may include other associated structures, such as isolation regions 116 and 118 in the semiconductor substrate 102, and insulating sidewalls 120 and 122 along the y-dimension sides of the gate 114 and gate dielectric 112.

The MIM capacitor 106 includes a lower metal plate (or element, or capacitor plate) 124, an upper metal plate (or element, or capacitor plate) 126, and a dielectric, or capacitor dielectric layer, 128 between the lower and upper metal plates 124 and 126. Each of the terms “lower” and “upper” is intended as a spatial reference relative to the upper surface 102US, that is, the lower metal plate 124 is closer than the upper metal plate 126 to the upper surface 102US, both in the y-dimension in FIG. 1 (and later figures). With this positioning and as better appreciated later, the lower metal plate 124 is formed before the upper metal plate 126, and various considerations arise in such formation, including whether to form at least one of those two plates as part of a step already in place for forming other metal interconnect structures.

In an example, the MIM capacitor 106 lower metal plate 124 has a thickness in a range from 1,000 Å to 2,000 Å (100 nm-200 nm). Further, the lower metal plate 124 includes a conductive material that has a relatively small grain size. For example, the lower metal plate 124 material may include grains having a size, e.g. a span, of 1.0 μm or less. Grain size may be measured with various methods. For example, one popular method for calculating grain size is known as the planimetric method. The planimetric method determines the grain size on an image (live or captured) by calculating the number of grains per unit area. Accordingly, grain size is generally an average “span” across different lines taken across the structure (or average across multiple structures). For the lower metal plate 124 and the desired grain size of 1.0 μm or less, as one example, certain materials may have a relatively small grain size of 0.5 μm, such as tungsten (W). As another example, certain materials may have a relatively small grain size of 0.1 μm, such as titanium (Ti) or titanium nitride (TiN). Still further, in one example, the entirety of the lower metal plate 124 is the small grain material. In another example, the plate may be provided by a plate stack, with different layers (each in a respective x/z plane) of different materials, but where at least 75% of the total thickness of the plate stack in the y-dimension is formed from the small grain material. In another example, the lower metal plate 124, whether of a single or multiple layers, excludes aluminum (Al). “excludes aluminum” means aluminum may be present, if at all, at a concentration less than 10 ppm (0.01 %). These attributes provide relatively little or no large grain metal in the lower plate, thereby eliminating potential drawbacks that may occur were the lower metal plate 124 to include larger grain metals (e.g., having a span greater than 1.0μm, or even 3.0 or greater) as part, or a majority of, the lower plate, particularly when the entirety of the plate (or plate stack) has a relatively large thickness (e.g., 1,000 Å (100 nm) or greater). For example, use of a material having large grains in the lower plate may tend to introduce surface unevenness or other surface irregularities which may then interface directly with the capacitor dielectric, or interface with another plate stack layer that then is correspondingly affected in its interface with the capacitor dielectric. Such irregularities may likewise cause uneven thickness or planarity of the capacitor dielectric, thereby potentially negatively affecting its reliability, performance, or achievement of intended specification. In contrast, in some examples, when lower metal plate 124 predominantly contains small grain materials, either as a homogenous material layer or having small grain materials constituting at least 75% of the y-dimension thickness of a heterogenous material layer, a relatively smooth surface of the lower metal plate 124 interfaces to the dielectric 128, which also may result in a more favorably uniform thickness (and planar shape) of the dielectric 128 as further detailed later.

In an example, the MIM capacitor 106 upper metal plate 126 is formed from a same metal as is used for other metal portions formed at a same time from the corresponding and concurrently-formed metal interconnect level. Particularly and as detailed below, the IC 100 includes various metal layers, typically numbered with an M1 metal interconnect layer closest to the upper surface 102US and thereafter ascending in number, so that FIG. 1 shows levels M1, M4, M5, and M6 (M2 and M3 are omitted as a portion of the cross-section is eliminated for simplicity). In the FIG. 1 example, the upper metal plate 126 is formed as part of the M5 metal layer and, accordingly, has a same material and thickness as that layer. For example, the metal may be substantially pure Al, and may have a relatively large grain size, for example of 3.0 μm or more. (The upper metal plate 126 may include a few percent of other elements, such as copper, e.g. to limit electromigration, and still be considered as “substantially pure”).

In an example, the MIM capacitor 106 dielectric 128 may be of various materials. Examples include silicon dioxide (SiO₂), silicon nitride (Si₃N₄), and others. Further, the y-dimension thickness of the dielectric 128 may be in a range from 100 Å to 500 Å (10 nm to 50 nm).

FIG. 1 further illustrates that the IC 100 includes the above-introduced plural metal interconnect layers M1 through M6, and it further includes plural dielectric layers, shown as a pre-metal dielectric layer PMD and a number of interlevel dielectric layers shown as ILD1, (ILD2 not shown), ILD3, ILD4, and ILD5, sometimes referred to as interconnect dielectric layers, where for convention each of the ILD layers has an integer indicator that matches the metal layer around which the ILD layer is formed (e.g., the ILD1 layer surrounds the M1 metal elements, the ILD4 layer surrounds the M4 elements, and so forth). Each of the metal interconnect layers M1 through M6 is patterned/etched to leave remaining portions of the respective layer, with each portion providing a metal element, which provides a physical point of potential electrical contact. Each of the PMD and ILD layers provides electrical isolation and a surface along which another layer or item may be formed, where in the example shown such surfaces are planarized. For example, above the PDM layer, the M1 layer includes metal contacts, or traces, 130, 132, and 134. Prior to forming those metal contacts, a respective hole for each metal contact is formed in the y-dimension through the PMD layer. Each formed hole is aligned to a point of contact below the hole in the y-dimension, and each hole is filled with metal to form a conductive via, thereby providing a vertical electrical path to the point of contact. For example, a conductive via 136 is formed to contact the first source/drain region 108, a conductive via 138 is formed to contact the second source/drain region 110, and a conductive via 140 is formed to contact the gate 114. Thereafter, respective metal contacts are formed to physically and electrically connect to each of the conductive vias, for example by forming (e.g., chemical vapor deposition (CVD)) the metal layer M1 and patterning and etching it such that remaining metal layer portions provide the metal contacts. For example, the metal contact 130 contacts the conductive via 136, the metal contact 132 contacts the conductive via 138, and the metal contact 134 contacts the conductive via 140. By way of example, FIG. 1 illustrates additional metal vias and contacts that provide an electrical coupling to the first source/drain region 108, including a metal via 148 through the ILD1 layer, a partial view of a metal via 144 through a portion of the ILD3 layer, an M4 metal contact 146 on an upper surface of the ILD3 layer, a metal via 148 through a portion of the ILD4 layer, an M5 metal contact 150 on the ILD4 layer, a metal via 152 through a portion of the ILD5 layer, and an M6 metal contact 154 on the ILD6 layer. Lastly, FIG. 1 also illustrates respective metal couplings to both the MIM capacitor 106 lower, or bottom, and upper, or top, metal plates 124 and 126. Particularly, a first metal coupling includes an ILD5 metal via 156 and an M6 metal contact 158, and a second metal coupling includes an ILD5 metal via 160 and an M6 metal contact 162.

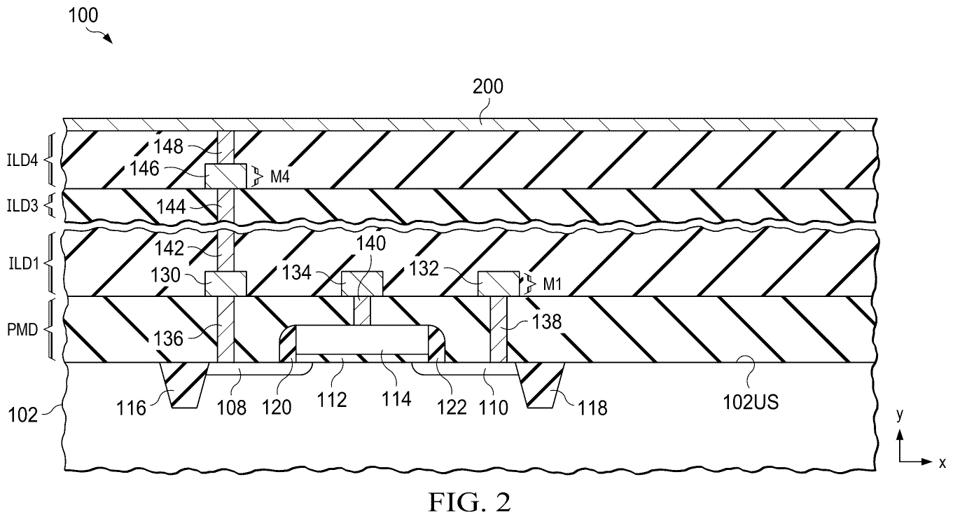

FIG. 2 illustrates the IC 100 at a processing step earlier in the formation of the above-introduced FIG. 1 structure, and to introduce additional details. In FIG. 2, the ILD4 layer is formed with a planar upper surface. For example, the ILD4 layer may be formed using CVD, such as plasma-enhanced CVD (PECVD) formation of a dielectric material, followed by planarization (e.g., by chemical mechanical planarization (CMP)). Next, a hole is formed through the ILD4 layer down to an upper surface of the M4 metal contact 146, and the hole is filled with metal to create the metal via 148. Hole formation may be achieved using photolithography and etch, and metal is formed in the hole, which may include one or more layers (e.g., barrier layer and seed layer) or electroplating. Annealing also may be used with either the ILD4 layer formation and the metal via fill, for example annealing the ILD4 may improve properties such as density, stress, adhesion relative to the underlying layer(s), and annealing the metal may improve such properties as grain structure, stress, adhesion, and impurity reduction.

After forming the ILD4 layer and the metal via 148, a conductive layer 200 is formed over the upper planar surface of the ILD4 layer, where the conductive layer 200 will provide metal for the FIG. 1 MIM capacitor 106 lower metal plate 124. Accordingly, the materials and thickness of the conductive layer 200 correspond to that introduced above for the lower metal plate 124, including a relatively small grain size (e.g., 1.0 μm or less), and a conductive material that provides the desired grain size (e.g., W, TiN, Ti). In the illustrated example, with the conductive layer 200 formed over the ILD4 layer, then the conductive layer 200 also provides a planar surface in the x/z plane.

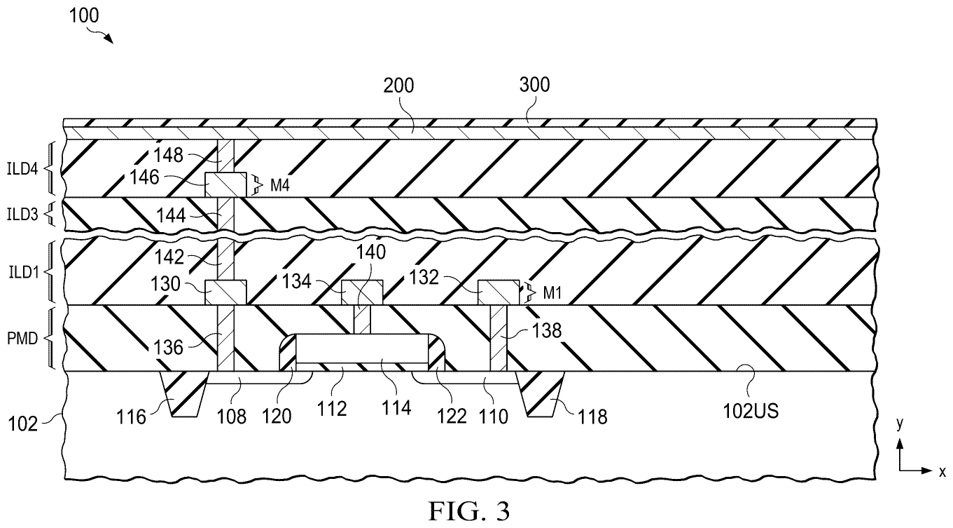

FIG. 3 illustrates the FIG. 2 IC 100 after additional processing. In FIG. 3, a dielectric layer 300 is formed over the conductive layer 200, where the dielectric layer 300 will provide the material for the FIG. 1 MIM capacitor 106 dielectric 128. Accordingly, the material(s) and thickness of the dielectric layer 300 correspond to that introduced above for the dielectric 128, including the formation of SiO₂, Si₃N₄, and/or others, with a y-dimension thickness in a range from 100 Å to 500 Å (10 nm to 50 nm). In the illustrated example, with the dielectric layer 300 formed over the conductive layer 200, then the dielectric layer 300 also provides a planar surface in the x/z plane. Additionally, and potentially importantly, the relatively small (and relatively consistent) grain size of the conductive layer 200, underlying the dielectric layer 300, creates a relatively smooth and planar upper surface for the conductive layer 200, which as shown in FIG. 3 interfaces to the dielectric layer 300. As a result, the dielectric layer 300 is formed with a corresponding and relatively uniform thickness (and planar surface), which serves as a structure from which the MIM capacitor 106 dielectric 128 is subsequently formed, thereby providing a comparable uniform thickness and planarity for the capacitor dielectric. Accordingly, it is expected that the MIM capacitor 106, including such a dielectric 128, may have one or more improved characteristics, including higher breakdown voltage, better matching with other die formed on a same wafer, better reliability/less chance of punch-through, and eliminating the need for newer hardware or alternative dielectric materials.

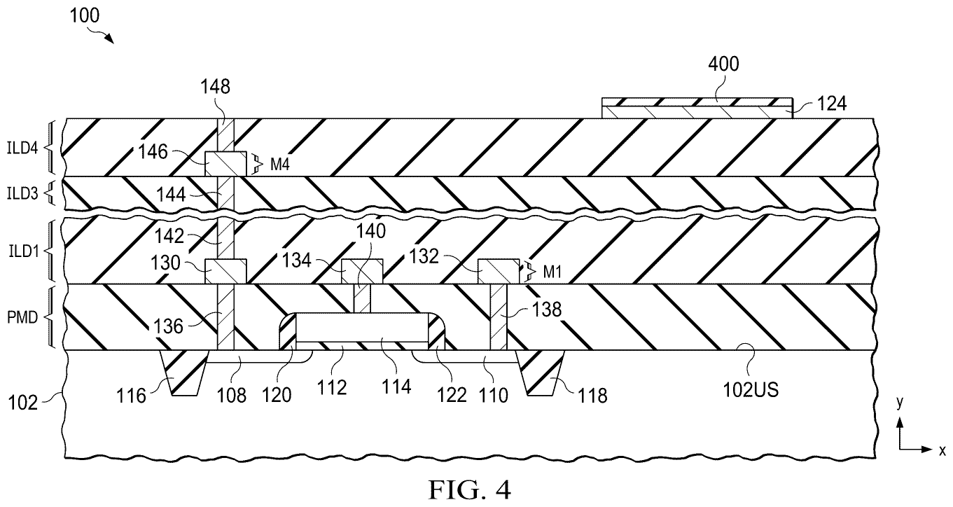

FIG. 4 illustrates the FIG. 3 IC 100 after additional processing. In FIG. 4, the FIG. 3 dielectric layer 300 and conductive layer 200 are patterned and etched, with the etch removing those layers for example down to the upper surface of the ILD4 layer. The post-etch remaining portion of the conductive layer 200 provides the FIG. 1 lower metal plate 124. The post-etch remaining portion of the dielectric layer 300 provides a precursor dielectric structure 400 that will be further processed to become the FIG. 1 dielectric 128.

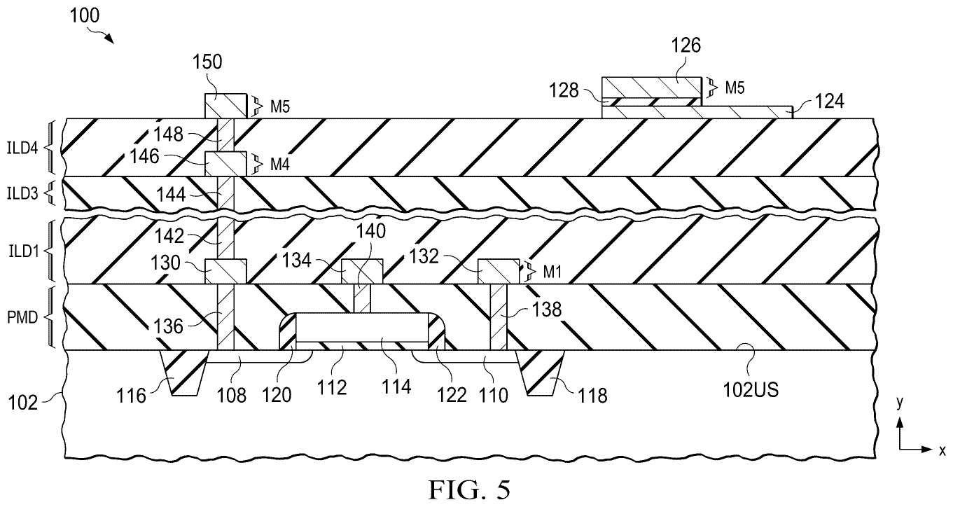

FIG. 5 illustrates the FIG. 4 IC 100 after additional processing. In FIG. 5, the M5 metal structures are formed. As with the other metal layers (M1 through M4 and M6), the M5 metal layer may be formed for example using CVD or physical vapor deposition (PVD). In an example, the metal layer thickness may depend on the metal level, where for example metal layers closer to the substrate upper surface 102US are thinner and have finer line widths than metals farther from the upper surface 102US. Increased thickness at higher metal levels may assist with maintaining signal integrity and reducing power losses. Lower metal layers may have thicknesses in a range of 350 nm to 500 nm, while upper metal layers may have thicknesses in a range of 10,000 Å to 20,000 Å (1000 nm to 2000 nm). Once the M5 metal layer is formed, it is patterned and etched so that remaining metal portions provide the M5 metal contact 150 and the upper metal plate 126. Notably, the M5 metal contact 150 will form atop the ILD4 layer, while the upper metal plate 126 will form atop the MIM capacitor 106 dielectric 128. In this regard, the upper horizontal (x/z plane) surfaces of the M5 metal contact 150 and the upper metal plate 126 are not co-planar, so considerations may arise in subsequent steps for providing contact to land at the upper surface of each of the M5 metal contact 150 and the upper metal plate 126.

After the structure of FIG. 5 is completed, electrical contacts may be made to the MIM capacitor 106 lower and upper plates 124 and 126, as shown in FIG. 1. In this regard and as shown in FIG. 1, the ILD5 layer is formed atop the ILD4 layer and the M5 metal contact 150 and the upper metal plate 126, and the metal vias 152, 156, and 160 are formed through a portion of the ILD5 layer. Formation of the ILD5 metal layer and metal vias may be similar as described above with respect to the earlier-formed ILD4 layer and the metal via 148. Thereafter, the M6 contacts 154, 158, and 162 are formed, with the metal contact 154 providing an electrical coupling to the transistor 104 first source/drain region 108, the metal contact 158 providing an electrical coupling to the upper metal plate 126, and the metal contact 162 providing an electrical coupling to the lower metal plate 124.

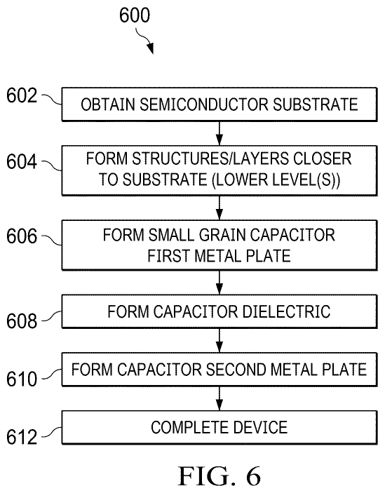

FIG. 6 is a flow diagram of an example method 600 summarizing various of the above-described steps for manufacturing the semiconductor device 100, for example as shown in FIGS. 1-5. The method 600 begins in a step 602, in which the FIG. 1 semiconductor substrate 102 is obtained. The semiconductor substrate 102 at this stage may be a bare wafer or may have one or more semiconductor features already formed on it, or such feature(s) may be formed as shown in in step 604, following the step 602. For example, the step 6 indicates forming structures and/or layers closer to the upper surface 102US of the semiconductor substrate 102. For example, FIG. 1 illustrates example structures for the transistor 104. Next, in a step 606, a first capacitor metal plate is formed that includes a small grain metal. Next, in a step 608, a capacitor dielectric is formed, for example in contact with the step 604 small grain metal plate. Next, in a step 610, a second capacitor metal plate is formed, for example in contact with the capacitor dielectric. In an example, the second capacitor metal plate may be made from a same metal as other metal contacts formed at the same time. Accordingly, if the other metal contacts are formed from a relatively large grain metal (e.g., Al), then the capacitor upper plate may also be from such a metal. Conversely, in an alternative, the capacitor upper plate also may include or be formed from small grain metal. Lastly, in a step 612, the semiconductor device 100 is completed, which may involve various steps depending on other components of the device and related technologies and considerations.

From the above, one skilled in the art should appreciate that examples are provided for semiconductor fabrication, for example with respect to an IC that includes a MIM capacitor. Such examples may provide various benefits, some of which are described above and including still others. Still additional modifications are possible in the described examples, and other examples are possible, within the scope of the following claims.

What is claimed is:

1. An integrated circuit (IC), comprising:
a semiconductor substrate having an upper surface;
an interconnect dielectric layer over the upper surface; and
a capacitor, including:
a top conductive plate over the interconnect dielectric layer;
a capacitor dielectric layer between the top conductive plate and the interconnect dielectric layer; and
a bottom conductive plate touching the capacitor dielectric layer and located between the capacitor dielectric layer and the interconnect dielectric layer, the bottom conductive plate having a grain span no larger than 1.0 μm.

2. The IC of claim 1, wherein the bottom conductive plate includes titanium nitride (TiN).

3. The IC of claim 1, wherein the top conductive plate includes a metallic material having grains with a span of 3.0 μm or greater.

4. The IC of claim 1, wherein the top conductive plate includes aluminum.

5. The IC of claim 1, wherein the bottom conductive plate is a homogenous layer.

6. The IC of claim 1, wherein the bottom conductive plate includes tungsten.

7. The IC of claim 1, wherein the bottom conductive plate includes titanium.

8. The IC of claim 1, wherein the top conductive plate is formed from a same metal layer as an interconnect trace layer.

9. The IC of claim 8, wherein the top conductive plate is a portion of a fifth or greater level metal trace layer over the semiconductor substrate.

10. The IC of claim 1, wherein the top conductive plate second has a thickness in a range between 5,000 Å and 15,000 Å.

11. The IC of claim 1, wherein the bottom conductive plate has a thickness in a range between 1,000 Å and 2,000 Å.

12. The IC of claim 1, wherein the bottom conductive plate has a mean grain size in a plane parallel to the upper surface of 0.5 μm or less.

13. An integrated circuit (IC), comprising:
a semiconductor substrate having an upper surface;
a first interconnect dielectric layer over the upper surface;
a titanium nitride capacitor plate directly on the first interconnect dielectric layer;
a capacitor dielectric layer directly on the titanium nitride capacitor plate;
an aluminum capacitor plate directly on the capacitor dielectric layer; and
a second interconnect dielectric layer touching the titanium nitride capacitor plate, the capacitor dielectric layer and the titanium nitride capacitor plate.

14. A method of forming an integrated circuit (IC), comprising:
forming an interconnect dielectric layer over an upper surface of a semiconductor substrate;
forming a top capacitor plate over the interconnect dielectric layer;
forming a capacitor dielectric layer between the top capacitor plate and the interconnect dielectric layer; and
forming a bottom capacitor plate touching the capacitor dielectric layer and located between the capacitor dielectric layer and the interconnect dielectric layer, the bottom capacitor plate having no grains with a span greater than 1.0μm.

15. The method of claim 14 wherein the bottom capacitor plate comprises titanium nitride.

16. The method of claim 14 wherein the bottom capacitor plate comprises tungsten.

17. The method of claim 14 wherein the bottom capacitor plate comprises elemental titanium.

18. The method of claim 14 further comprising forming a metal contact over the interconnect dielectric layer, wherein the top capacitor plate and the metal contact are formed from a same metal layer.

19. The method of claim 18 wherein the same metal layer is an aluminum layer.

20. The method of claim 14 further comprising connecting a first vertical metal via to the bottom capacitor plate and connecting a second vertical metal via to the top capacitor plate.
